(19) United States
(12) Patent Application Publication
(10) Pub. No.: US 2002/0160564 A1
(43) Pub. Date: Oct. 31, 2002

(54) Semiconductor device having conductive layer within field oxide layer and method for forming the same

(76) Inventor: Yeon-Cheol Heo, Ichon-Shi (KR)

Correspondence Address: BLAKELY SOKOLOFF TAYLOR & ZAFMAN, 12400 WILSHIRE BOULEVARD, SEVENTH FLOOR, LOS ANGELES, CA, 90025, US

(21) Appl. No.: 09/538,126

(22) Filed: Mar. 29, 2000

(30) Foreign Application Priority Data
Mar. 29, 1999 (KR) 1999/10766

(51) Int. Cl. H01L 21/8238

(52) U.S. Cl. 438/221

(57) ABSTRACT

A method for forming a semiconductor device having a field oxide layer for isolating elements from each other, wherein the semiconductor device contains a field region and an active region, the active region having a junction region and a channel region, includes the steps of: a) providing a semiconductor structure having a trench in the field region; b) forming a first field insulating layer into the trench; c) forming a conductive layer on the first field insulating layer to fill a predetermined portion of the trench; and d) forming a second field insulating layer on the conductive layer to fill the remaining portion of the trench, thereby reducing an influence of an electric field caused by a potential difference between a semiconductor substrate and a junction region.

### FIELD OF THE INVENTION

The present invention relates to a semiconductor device having a field oxide layer for isolating elements, formed on a semiconductor wafer, from each other; and, more particularly, to a semiconductor device having a conductive layer within a field oxide layer and a method for forming the same.

### DESCRIPTION OF THE PRIOR ART

As is well known to those skilled in the art, semiconductor devices, such as SRAM (static random access memory), DRAM (dynamic random access memory) and FeRAM (ferroelectric random access memory), includes an active region and a field region. A plurality of elements such as transistors are formed in the active region. Source/drain junction regions are also formed in the active region. A plurality of field oxide layers for isolating the elements from each other are formed in the field region.

With semiconductor devices becoming increasingly integrated, a formation of the field oxide layer becomes important. As one of well-known methods for forming the field oxide layer in highly integrated semiconductor device, a local oxidation of silicon (LOCOS) process is widely used. Another method is a shallow trench isolation (STI) process. The STI process has an advantage that the field oxide layer can be prevented from being formed thinly in a thickness at narrow region. Furthermore, the field oxide layer can also be prevented from being formed to thickly in a thickness at edges of the active regions.

As a chip size becomes much smaller, however, the field oxide layer also becomes thinner, so that a threshold voltage in the semiconductor device is undesirably varied due to an electric field caused by a potential difference between a junction region and a semiconductor substrate. In addition, the semiconductor device may be affected by potential variations in neighboring elements thereof.

FIG. 1A is a diagram showing a plane view of a semiconductor device such as dynamic random access memory (DRAM) cell. FIG. 1B is a cross-sectional view taken along the line A-A′. A reference numeral 10 represents a semiconductor substrate, 11 a field oxide layer, 14 a gate insulating layer, 15 a gate electrode, and 16 a junction region, respectively. As shown in FIG. 1B, the field oxide layer is formed in the field region and the junction regions and the channel region are formed in the active region.

Hereinafter, a method for forming a conventional semiconductor device will be described with reference to FIGS. 2A to 2D.

Referring to FIG. 2A, an oxide layer 11 and a nitride layer 12 are sequentially formed on a semiconductor substrate 10. Next, a mask (not shown) defining a plurality of field regions is formed on the nitride layer 12. Then, the nitride layer 12, the oxide layer 11 and a portion of the semiconductor substrate 10 are selectively etched to form trenches in the field regions.

Referring to FIG. 2B, after removing the mask, a field insulating layer 13 is formed into the trenches and over the nitride layer 12 and then, a chemical mechanical polishing (CMP) process or an etch-back process is performed to leave the field insulating layer 13 only at the inside of the trenches.

Referring to FIG. 2C, the nitride layer 12 and the oxide layer 11 are sequentially etched to complete the formation of the field oxide layers.

Referring to FIG. 2D, a gate insulating layer 14, a gate electrode 15 and a junction region 16 are sequentially formed. Therefore, a channel region is formed between the junction regions 16 and located beneath the gate electrode 15.

At this point, since the field insulating layer 13 is a non-conductive layer, an electric field caused by a potential difference between the channel region and the junction region is transmitted to the channel region without any attenuation. Furthermore, the field insulating layer 13 forms a capacitive element together with the junction regions and the channel region. That is, the field insulating layer 13 serves as a dielectric layer of the capacitive element. Accordingly, a variation in a potential of the junction region results in a variation in a potential of the channel region beneath the gate electrode.

In case of N-channel enhancement MOSFET (metal oxide semiconductor field effect transistor), if a potential of the junction regions 16 is higher than that of the semiconductor substrate 10, a potential of the channel region, especially a portion neighboring to the field region, becomes higher than that of the semiconductor substrate 10.

In view of a depletion region in the active region, carriers in the active region neighboring to the field region are depleted due to a variation in a potential of the junction regions 16, resulting in a decrease of a threshold voltage of the semiconductor device. That is due to the electric field caused by a potential difference between the semiconductor substrate and the junction regions.

FIG. 3 is a simulation diagram showing a potential distribution by using equi-potential lines with respect to a distance from a center of the channel region and a depth from a surface of semiconductor substrate in FIG. 2D, when the potential of the junction regions is higher than that of the semiconductor substrate. As can be seen from FIG. 3, the intervals between the equi-potential lines is very narrow and the slope of the equi-potential line is descended steeply in the field region. Therefore, the potential of the channel region is easily changeable due to the variation in the potential of the junction regions, thereby degrading a device characteristic.

### SUMMARY OF THE INVENTION

It is, therefore, an object of the present invention to provide a semiconductor device having a conductive layer within a field oxide layer and a method for the same, reducing an influence of electric field caused by variations in potential of neighboring elements.

In accordance with an aspect of the present invention, there is provided a method for forming a semiconductor device having a field oxide layer for isolating elements from each other, wherein the semiconductor device contains a field region and an active region, the active region having a junction region and a channel region, comprising the steps of: a) providing a semiconductor structure having a trench in the field region; b) forming a first field insulating layer into the trench; c) forming a conductive layer on the first field insulating layer to fill a predetermined portion of the trench; and d) forming a second field insulating layer on the conductive layer to fill the remaining portion of the trench.

In accordance with another aspect of the present invention, there is provided a semiconductor device having a field oxide layer for isolating elements from each other, wherein the semiconductor device includes a field region and an active region, the active region having a junction region and a channel region, comprising: a semiconductor substrate having a trench in the field region; a first field insulating layer formed into the trench; a conductive layer filling a predetermined portion of the trench; and a second field insulating layer formed on the conductive layer, wherein the second insulating layer fills the remaining portion of the trench.

### BRIEF DESCRIPTION OF THE DRAWINGS

Other objects and aspects of the invention will become apparent from the following description of the embodiments with reference to the accompanying drawings, in which:

FIG. 1A is a plane view showing a typical DRAM cell structure;

FIG. 1B is a cross-sectional view taken along the line A-A′ of FIG. 1A;

FIGS. 2A to 2D are cross-sectional views describing sequential steps for forming a conventional semiconductor device;

FIG. 3 is a simulation diagram showing a potential distribution by using equi-potential lines in FIG. 2D;

FIGS. 4A to 4D are cross-sectional views showing sequential steps for forming a semiconductor device in accordance with an embodiment of the present invention;

FIGS. 5A to 5E are cross-sectional views showing sequential steps for forming a semiconductor device in accordance with another embodiment of the present invention; and

FIG. 6 is a simulation diagram showing a potential distribution by using equi-potential lines in FIG. 5E.

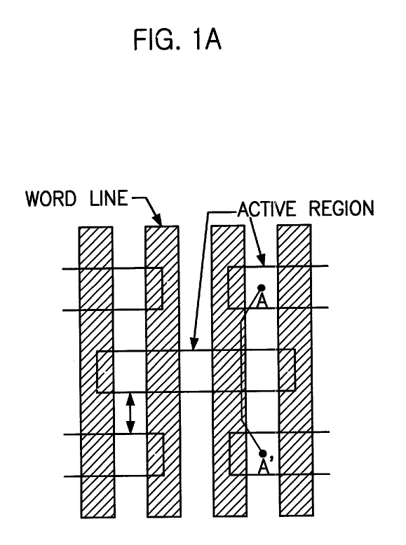

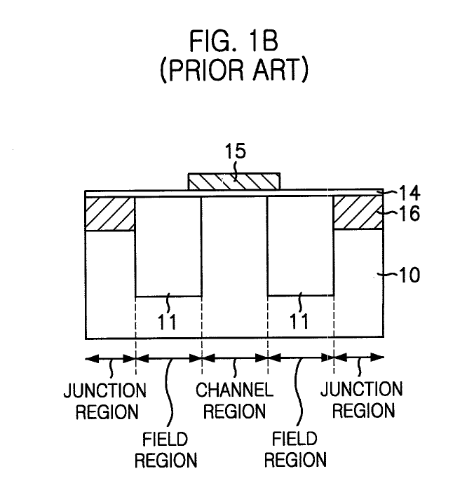

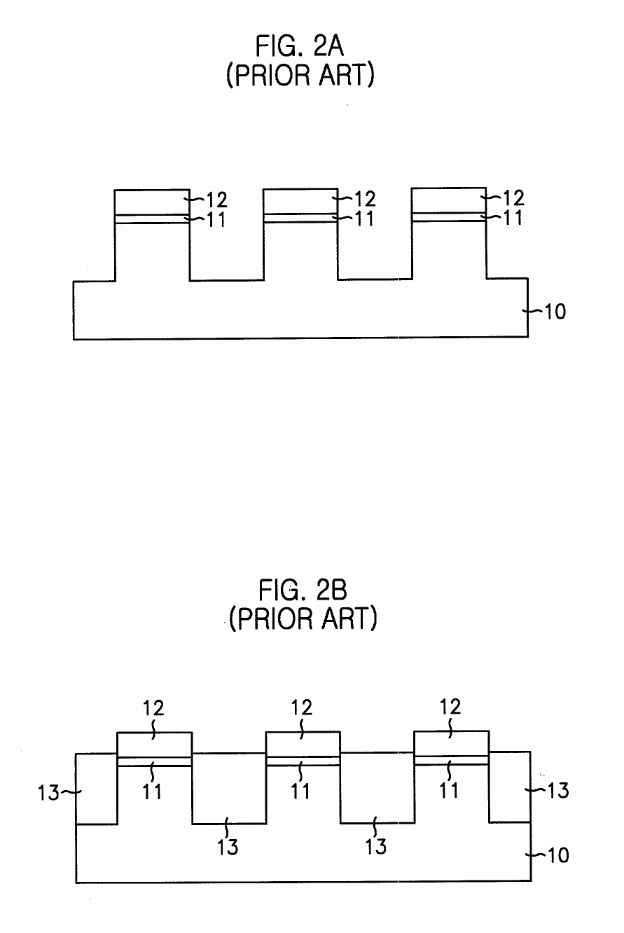

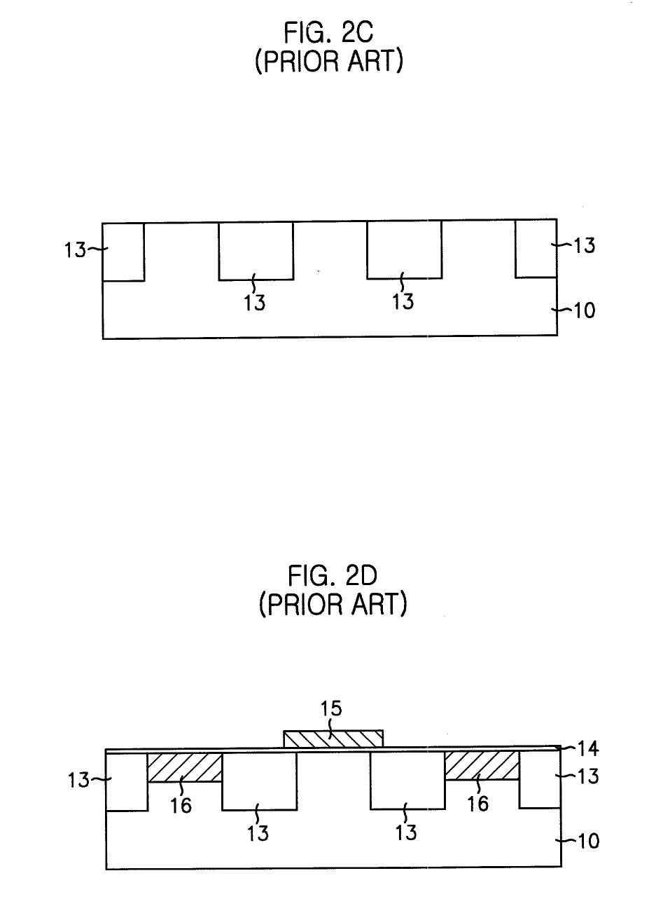

### DETAILED DESCRIPTION OF THE PREFERRED EMBODIMENTS

The present invention provides a semiconductor device having a conductive layer within a field oxide layer, capable of reducing an undesirable influence due to variations in neighboring elements and improving a packing density and characteristic of the semiconductor device.

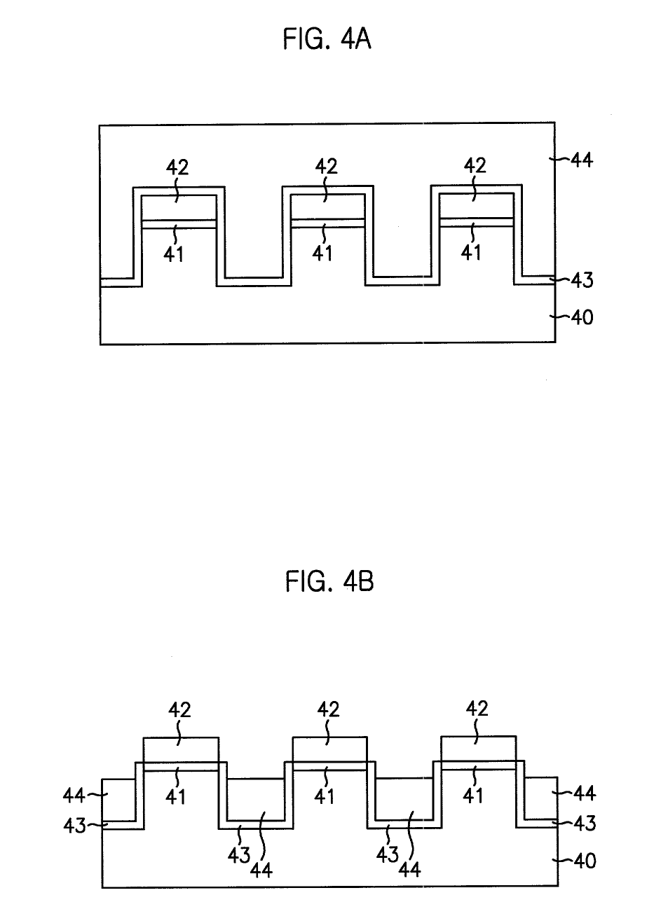

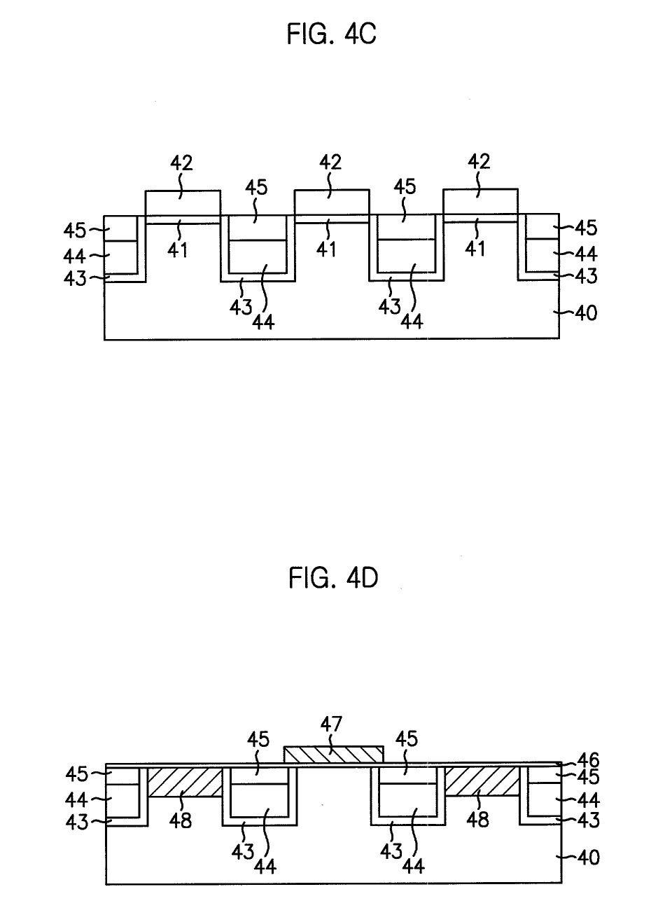

A method for forming the semiconductor device in accordance with an embodiment of the present invention will be described below with reference to FIGS. 4A to 4D.

Referring to FIG. 4A, an oxide layer 41 and a nitride layer 42 are sequentially formed on a semiconductor substrate 40. Next, a mask (not shown) defining a plurality of field regions is formed on the nitride layer 42. Then, the nitride layer 42, the oxide layer 41 and a portion of the semiconductor substrate 40 are selectively etched to form trenches in the field regions.

Next, after removing the mask, a first field insulating layer 43 is formed on sidewalls and bottom portion of the trenches by a deposition operation or an oxidation operation. In case of the deposition operation, the first field insulating layer 43 is formed on an entire surface of the resulting structure. On the other hand, in case of the oxidation operation of the semiconductor substrate 40, the first field insulating layer 43 is formed only on an exposed portion of the semiconductor substrate 40 within the trenches. Furthermore, the first field insulating layer 43 can be a nitride layer or an oxide layer.

Then, a conductive layer 44 is formed on the first field insulating layer 43. The conductive layer 44 can be selected from the group consisting of a single-crystal silicon layer, a polycrystalline silicon layer and an amorphous silicon layer, or a combination thereof.

Referring to FIG. 4B, a chemical mechanical polishing (CMP) process or an etch-back process is performed on the conductive layer 44 and the first field insulating layer 43, thereby exposing the nitride layer 42 and leaving the conductive layer 44 only within the trenches. Consequently, a predetermined portion of each trench is filled with the conductive layer 44. At this time, it is preferable to form the conductive layer 44 having a thickness of at least above Debye length.

Referring to FIG. 4C, a second field insulating layer 45 is formed on the conductive layer 44 by an oxidation operation or a deposition operation. Then, the chemical mechanical polishing (CMP) process or the etch-back process is performed to leave the second field insulating layer 45 only at the trenches, thereby filling the remaining portion of each trench. Consequently, each trench is filled with the first field insulating layer 43, the conductive layer 44 and the second field insulating layer 45 in a stack structure. The second field insulating layer 45 can be an oxide layer.

Referring to FIG. 4D, the nitride layer 42 and the oxide layer 41 are etched. Then, a gate oxide layer 46 and a gate electrode 47 are sequentially formed on a resulting structure by well-known operations. Finally, junction regions 48 are formed by an ion implantation.

Referring again to FIG. 4D, a semiconductor device in accordance with an embodiment of the present invention includes the semiconductor substrate 40 having the trenches, the first field insulating layer 43 formed on sidewalls and bottom portion of the trenches. The conductive layer 44 is formed on the first insulating layer to fill a predetermined portion of each trench, and the second field insulating layer 45 is formed on the conductive layer to fill the remaining portion of each trench.

At this time, the first field insulating layer 43 is formed with a nitride layer or an oxide layer and the conductive layer 44 is selected from the group consisting of a single-crystal silicon layer, a polycrystalline silicon layer and an amorphous silicon layer, or a combination thereof. It is preferable to form the conductive layer 44 having a thickness of at least above Debye length. Also, the second field insulating can be an oxide layer.

The semiconductor device further includes the gate insulating layer 46 formed on an entire structure, the gate electrode 47 formed on the gate insulating layer 46, and junction regions 48 formed in the active region by ion implantation.

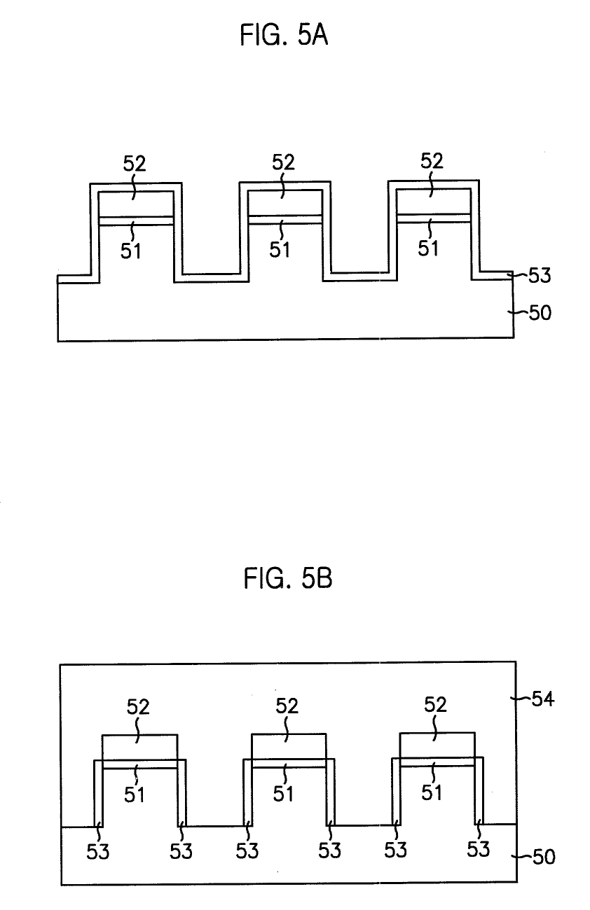

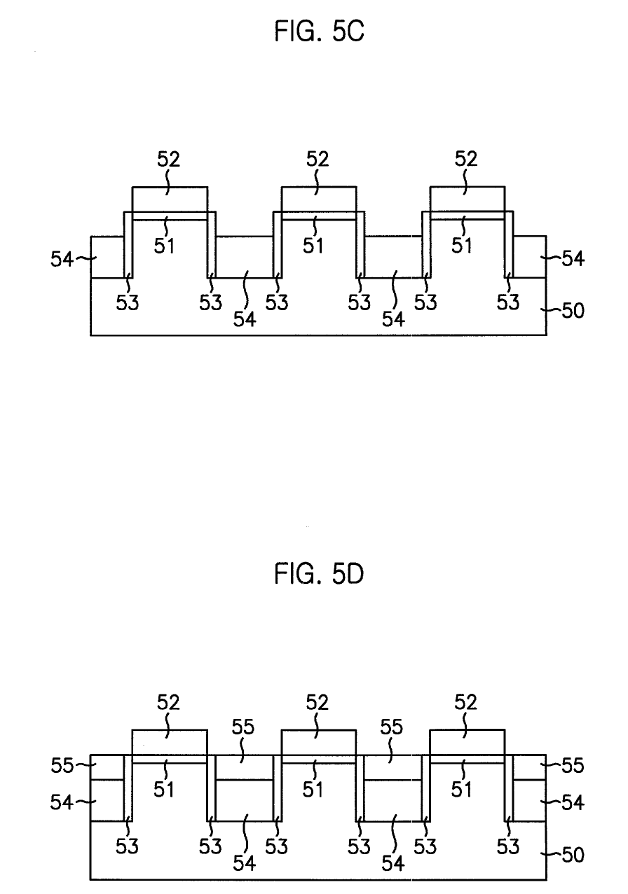

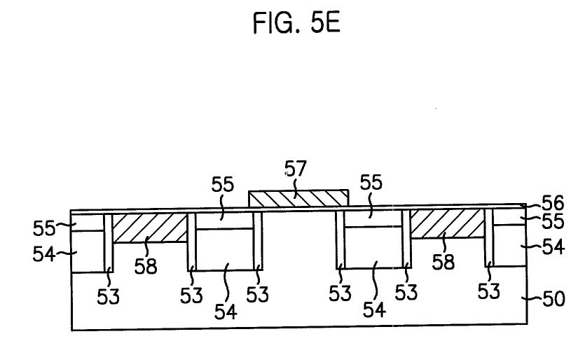

A method for forming a semiconductor device in accordance with another embodiment will be described below with reference to FIGS. 5A to 5E.

Referring to FIG. 5A, an oxide layer 51 and a nitride layer 52 are sequentially formed on a semiconductor substrate 50. Next, a mask (not shown) defining a plurality of field regions is formed on the nitride layer 52. Then, the nitride layer 52, the oxide layer 51 and a portion of the semiconductor substrate 50 are selectively etched to form trenches in the field regions.

Next, after removing the mask, a first field insulating layer 53 is formed on a resulting structure by a deposition operation or an oxidation operation. In case of the deposition operation, the first field insulating layer 53 is formed on an entire surface of the resulting structure. On the other hand, in case of the oxidation operation of the semiconductor substrate 50, the first field insulating layer 53 is formed only on an exposed portion of the semiconductor substrate 50 within the trenches. Furthermore, the first field insulating layer 53 can be a nitride layer or an oxide layer.

Referring to FIG. 5B, an anisotropic etching process is performed to leave the first field insulating layer 53 only at sidewalls of the trenches. Then, a conductive layer 54 is formed on an entire structure. The conductive layer 54 can be selected from the group consisting of a single-crystal silicon layer, a polycrystalline silicon layer and an amorphous silicon layer, or a combination thereof.

Referring to FIG. 5C, a chemical mechanical polishing (CMP) process or an etch-back process is performed on the conductive layer 54, thereby exposing the nitride layer 52 and leaving the conductive layer 54 only within the trenches. Consequently, a predetermined portion of each trench is filled with the conductive layer 54. At this time, it is preferable to form the conductive layer 54 having a thickness of at least above Debye length.

Referring to FIG. 5D, a second field insulating layer 55 is formed on the conductive layer 54 by an oxidation operation or a deposition operation. Then, the chemical mechanical polishing (CMP) process or the etch-back process is performed to leave the second field insulating layer 55 only at the trenches, thereby filling the remaining portion of the trenches. Consequently, each trench is filled with the first field insulating layer 53 on the sidewalls thereof, the conductive layer 54 and the second field insulating layer 55 in a stack structure. The second field insulating layer 55 can be an oxide layer.

Referring to FIG. 5E, the nitride layer 52 and the oxide layer 51 are etched. Then, a gate oxide layer 56 and a gate electrode 57 are sequentially formed on a resulting structure by well-known operations. Finally, junction regions 58 are formed in the active region by an ion implantation.

Referring again to FIG. 5E, a semiconductor device in accordance with another embodiment of the present invention includes the semiconductor substrate 50 having the trench, the first field insulating layer 53 formed on sidewalls of the trenches, the conductive layer 54 which is formed on the first field insulating layer 53 to fill a predetermined portion of each trench. At this time, it is preferable to form the conductive layer 54 having a thickness of at least above a Debye length.

The second field insulating layer 55 is formed on the conductive layer 54 to fill the remaining portion of each trench. At this time, the first field insulating layer 53 is formed with a nitride layer or an oxide layer and the conductive layer 54 is selected from the group consisting of a single-crystal silicon layer, a polycrystalline silicon layer and an amorphous silicon layer, or a combination thereof. Also, the second field insulating layer 55 can be an oxide layer.

The semiconductor device further includes the gate insulating layer 56 formed on an entire structure, the gate electrode 57 formed on the gate insulating layer 56, and junction regions 58 formed in the active region by ion implantation.

Compared with the conventional field oxide layer which is filled only with the insulating layer, the field oxide layer according to the present invention is filled with the conductive layer as well as the insulating layer, as shown in FIG. 4D and FIG. 5E. Therefore, in the channel region, an influence by electric field due to a potential difference between the semiconductor substrate and the junction regions can be reduced by movement of carriers existing in the conductive layer. Additionally, an increase of the potential in the channel region and a depletion region neighboring to the field region can be effectively prevented.

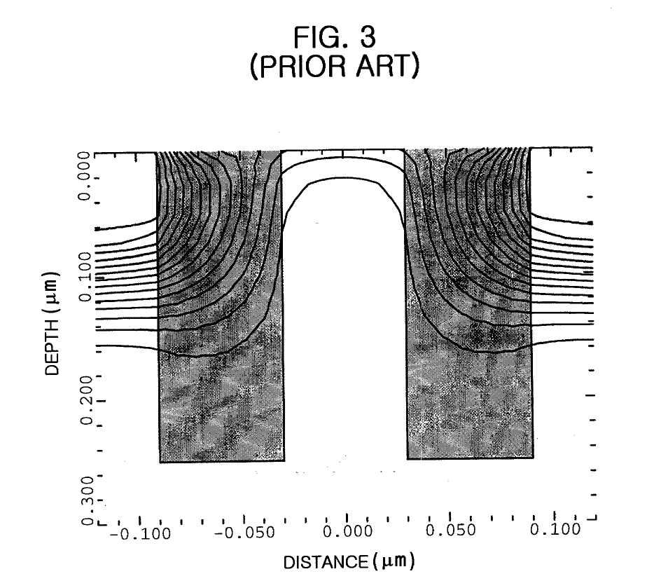

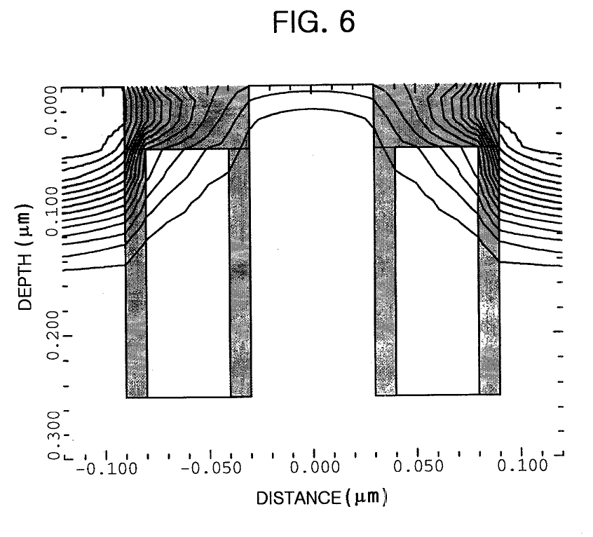

FIG. 6 is a simulation diagram showing a potential distribution by using equi-potential lines with respect to a distance from a center of the channel region and a depth from a surface of semiconductor substrate in FIG. 5E, when the potential of the junction regions is higher than that of the semiconductor substrate. Compared with FIG. 3, the intervals between the equi-potential lines is wide and the slope of the equi-potential line is descended smoothly in the field region. That is, the channel region is not sensitive to the variation in the potential of the junction regions. Furthermore, device characteristic such as a threshold voltage can be prevented from being varied due to a potential variation in the neighboring element and the junction regions.

Although the preferred embodiments of the invention have been disclosed for illustrative purposes, those skilled in the art will appreciate that various modifications, additions and substitutions are possible, without departing from the scope and spirit of the invention as disclosed in the accompanying claim.

What is claimed is:

1. A method for forming a semiconductor device having a field oxide layer for isolating elements from each other, wherein the semiconductor device contains a field region and an active region, the active region having a junction region and a channel region, comprising the steps of:
a) providing a semiconductor structure having a trench in the field region;
b) forming a first field insulating layer into the trench;
c) forming a conductive layer on the first field insulating layer to fill a predetermined portion of the trench; and
d) forming a second field insulating layer on the conductive layer to fill the remaining portion of the trench.

2. The method as recited in claim 1, wherein the conductive layer is selected from the group consisting of a single-crystal silicon layer, a polycrystalline silicon layer and an amorphous silicon layer, or a combination thereof.

3. The method as recited in claim 2, wherein the conductive layer has a thickness of above Debye length.

4. The method as recited in claim 2, wherein the first field insulating layer is formed with one of a nitride layer and an oxide layer.

5. The method as recited in claim 4, wherein the first field insulating layer is formed on sidewalls and bottom portion of the trench by carrying out a deposition process.

6. The method as recited in claim 1, wherein the second field insulating layer is formed with an oxide layer.

7. The method as recited in claim 4, wherein the step a) includes the steps of:
a1) preparing a semiconductor substrate;
a2) sequentially forming an oxide layer and a nitride layer on the semiconductor substrate;
a3) forming an mask on the nitride layer to define the field region;
a4) selectively etching the nitride layer, the oxide layer and a portion of the semiconductor substrate to form the trench; and
a5) removing the mask.

8. The method as recited in claim 7, wherein the first field insulating layer is formed on an exposed portion of the semiconductor substrate within the trench by an oxidation process.

9. The method as recited in claim 7, wherein the step c) includes the steps of:
c1) forming the conductive layer into the trench and over the semiconductor structure; and
c2) performing one of a chemical mechanical polishing process and an etch-back process to expose the oxide layer.

10. The method as recited in claim 9, wherein the step d) includes the steps of:
d1) forming the second field insulating layer on an entire structure;
d2) leaving the second field insulating layer on the remaining portion of the trench by performing one of a chemical mechanical polishing process and an etch-back process; and
d3) etching the nitride layer and the oxide layer.

11. The method as recited in claim 7, further comprising the steps of:
e) forming a gate insulating layer over the resulting structure;
f) forming a gate electrode on the gate insulating layer; and
g) forming a junction region in the active region by an ion implantation.

12. The method as recited in claim 1, further comprising the step of performing an anisotropic etching process after the step b), so that the first field insulating layer is substantially left only on sidewalls of the trench.

13. A semiconductor device having a field oxide layer for isolating elements from each other, wherein the semiconductor device includes a field region and an active region, the active region having a junction region and a channel region, comprising:
a semiconductor substrate having a trench in the field region;
a first field insulating layer formed into the trench;
a conductive layer filling a predetermined portion of the trench; and
a second field insulating layer formed on the conductive layer, wherein the second insulating layer fills the remaining portion of the trench.

14. The semiconductor device as recited in claim 13, wherein the conductive layer is selected from the group consisting of a single-crystal silicon layer, a polycrystalline silicon layer and an amorphous silicon layer, or a combination thereof.

15. The semiconductor device as recited in claim 14, wherein the conductive layer has a thickness of above Debye length.

16. The semiconductor device as recited in claim 13, wherein the conductive layer is formed on sidewalls of the trench.

17. The semiconductor device as recited in claim 13, wherein the conductive layer is formed on sidewalls and bottom portion of the trench.

18. The semiconductor device as recited in claim 14, wherein the first field insulating layer is one of a nitride layer and an oxide layer.

19. The semiconductor device as recited in claim 13, wherein the second field insulating is an oxide layer.

20. The semiconductor device as recited in claim 13, further comprising:
a gate insulating layer formed on an entire structure;
a gate electrode formed on the gate insulating layer; and
a junction region formed in the active region by ion implantation process.
